(19) United States
(12) Patent Application Publication
(10) Pub. No.: US 2026/0304854 A1
(43) Pub. Date: Oct. 1, 2026

(54) SIC TRENCH MOSFET WITH TRENCH BOTTOM PROTECTION STRUCTURE AND METHOD FOR MANUFACTURING THE SAME

(71) Applicant: POWER MASTER SEMICONDUCTOR CO., LTD., Cheongju-si (KR)

(72) Inventors: Hong Ki KIM, Incheon (KR); Hyung Jin LEE, Incheon (KR)

(73) Assignee: POWER MASTER SEMICONDUCTOR CO., LTD., Cheongju-si (KR)

(21) Appl. No.: 19/635,588

(22) Filed: Mar. 31, 2026

(30) Foreign Application Priority Data
Apr. 1, 2025 (KR) 10-2025-0042465

(51) Int. Cl. H10D 62/10; H10D 30/01; H10D 30/66; H10D 62/832; H10P 30/20

(52) U.S. Cl. CPC H10D 62/105; H10D 30/0297; H10D 30/668; H10D 62/8325; H10P 30/212

(57) ABSTRACT

The present disclosure relates to a SiC trench MOSFET having a trench bottom protection structure for preventing destruction of a trench bottom oxide by blocking concentration of an electric field at the trench bottom oxide while simplifying a manufacturing process. More specifically, the present disclosure relates to a SiC MOSFET comprising: a semiconductor layer of a first conductivity type; a gate trench formed on an upper surface of the semiconductor layer; a source well structure of a second conductivity type formed on the upper surface of the semiconductor layer at a predetermined distance from the gate trench; a body region of the second conductivity type formed on the upper surface between the gate trench and the source well structure; a source region of the first conductivity type formed on an upper surface of the body region; and a trench bottom protection structure provided at a bottom of the gate trench.

### CROSS REFERENCE TO RELATED APPLICATION

The present application claims the right of priority to and the benefits of Korean Application No. 10-2025-0042465 having a filing date of Apr. 1, 2025, the content of which is hereby incorporated by reference in its entirety.

### BACKGROUND OF THE INVENTION

The present disclosure relates to a SiC trench MOSFET, and more particularly, to a SiC trench MOSFET for solving a problem of gate oxide destruction by reducing an electric field formed in the gate oxide through a trench bottom protection structure.

Silicon carbide (SiC) is a wide bandgap semiconductor having a higher bandgap than silicon, with a dielectric breakdown field of 3×10⁶ V/cm, which is approximately 10 times that of silicon, an energy bandgap of 3.26 eV, which is approximately 3 times that of silicon, and a thermal conductivity of 3.7 W/cmK, which is approximately 3 times that of silicon. Accordingly, SiC exhibits characteristics of having a high breakdown voltage compared to silicon while having low loss and excellent heat dissipation. As a result, when fabricating a power semiconductor device of the same rating, not only may a cooling system be minimized, but a device size may also be reduced, thereby lowering production costs.

In particular, SiC facilitates substrate formation through single crystal growth, and since a device fabrication process is similar to a conventional silicon process, much research has been conducted on SiC as a semiconductor material to replace silicon power devices.

Such SiC power semiconductor devices may increase a power density by 3 to 10 times compared to silicon-based power semiconductor devices. When applied as a power switching device due to the excellent physical properties of SiC, the device may be manufactured to a size of 1/10 compared to a switching device using silicon, and power loss caused by the switching device may also be significantly reduced.

Since the dielectric breakdown field of SiC is approximately 10 times higher than that of silicon, and a thickness of a drift layer (drift region) for withstanding the same voltage may be manufactured to approximately 1/10 compared to silicon, an on-resistance may be significantly reduced at the same voltage.

In general, in a SiC semiconductor, a high electric field is formed at a bottom of a gate oxide of a trench structure, and such a high electric field causes dielectric breakdown of the gate oxide, which acts as a factor degrading reliability. To solve this problem, a deep P-well structure (hereinafter referred to as a deep P-well structure) may be considered.

Such a deep P-well structure is effective because an electric field is formed lower as the depth increases. However, when the depth of the deep P-well structure becomes deeper than the trench, a narrowing region is formed in an electron movement path, and there is a problem that current crowding may be intensified.

Therefore, there is a need for research on structural improvement capable of reducing a strength of an electric field formed at a bottom of a trench.

### SUMMARY

An object of the present disclosure is to provide a protection structure for preventing destruction of a trench bottom oxide caused by a high electric field in a trench-structured SiC MOSFET, and to provide a technology for improving stability of a semiconductor device therethrough.

Another object of the present disclosure is to provide a technology for implementing a structure that alleviates a current crowding problem that may occur when a depth of a deep P-well becomes deeper than a trench, thereby making a current path uniform and reducing power loss and thermal stress.

Another object of the present disclosure is to provide a semiconductor device that simultaneously satisfies trench bottom oxide protection and current spreading effects by combining first and second bottom protection structures.

Embodiments of the present disclosure are not limited to the above-described objects, and other objects not mentioned herein will be clearly understood by those skilled in the art from the description below.

A SiC MOSFET according to an embodiment of the present disclosure may include: a semiconductor layer of a first conductivity type; a gate trench formed on an upper surface of the semiconductor layer; a source well structure of a second conductivity type formed on the upper surface of the semiconductor layer at a predetermined distance from the gate trench; a body region of the second conductivity type formed on the upper surface between the gate trench and the source well structure; a source region of the first conductivity type formed on the upper surface of the body region; and a trench bottom protection structure provided at a bottom of the gate trench.

The trench bottom protection structure may include: a first bottom protection structure forming a second conductivity type region formed to a predetermined depth downward from a bottom of the trench; and a second bottom protection structure having a shape surrounding the first bottom protection structure and forming a first conductivity type region.

The second bottom protection structure may be provided in a hemispherical shape at the bottom of the trench, and the first bottom protection structure may be inserted inside the hemispherical shape, such that a bottom and sides of the first bottom protection structure are surrounded by the second bottom protection structure.

The second bottom protection structure may be formed being confined to a region directly below the bottom of the trench, contacting at least a portion of the region below the bottom of the trench, and not extending upward along an outer sidewall of the trench.

Here, a doping concentration of the second bottom protection structure may be formed higher than a doping concentration of the semiconductor layer.

Here, the first bottom protection structure may be a structure forming a second conductivity type region at the bottom of the trench in order to reduce an electric field applied to a trench bottom oxide.

Here, the second bottom protection structure may be a structure forming a first conductivity type region surrounding the first bottom protection structure in order to widely distribute current and reduce power loss and thermal stress.

Here, a depth of the source well structure may be formed deeper than a bottom of the gate trench.

A method for manufacturing a SiC MOSFET according to another aspect of the present disclosure includes the following steps.

A method for manufacturing a SiC MOSFET according to an embodiment of the present disclosure may include: forming a body region of a second conductivity type on an upper surface of a semiconductor layer of a first conductivity type; forming a source region of the first conductivity type on an upper surface of the body region; forming a gate trench on the upper surface of the semiconductor layer; forming a source well structure of the second conductivity type on the upper surface of the semiconductor layer at a predetermined distance from the gate trench; and forming a trench bottom protection structure at a bottom of the formed gate trench.

The forming of the trench bottom protection structure may include: performing a first conductivity type implant on a bottom of the trench to form a second bottom protection structure; filling an interior of the trench with Poly-Si; etching the filled Poly-Si to form a spacer; performing a second conductivity type implant on the bottom of the trench to form a first bottom protection structure; additionally performing the first conductivity type implant to reinforce the second bottom protection structure; and removing the formed spacer.

Here, the trench bottom protection structure may include: a first bottom protection structure forming a second conductivity type region formed to a predetermined depth downward from the bottom of the trench; and a second bottom protection structure having a shape surrounding the first bottom protection structure and forming a first conductivity type region, wherein a doping concentration of the second bottom protection structure may be formed higher than a doping concentration of the semiconductor layer.

Here, the first bottom protection structure may be a structure forming a second conductivity type region at the bottom of the trench in order to reduce an electric field applied to a trench bottom oxide.

Here, the second bottom protection structure may be a structure forming a first conductivity type region surrounding the first bottom protection structure in order to widely distribute current and reduce power loss and thermal stress.

Here, a depth of the source well structure may be formed deeper than a bottom of the gate trench.

Effects of the SiC trench MOSFET having a trench bottom protection structure and the method for manufacturing the same according to the present disclosure will be described as follows.

According to at least one of the embodiments of the present disclosure, there is an advantage that a protection structure for preventing destruction of a trench bottom oxide caused by a high electric field in a trench-structured SiC MOSFET is provided, thereby improving stability of a semiconductor device.

In addition, according to at least one of the embodiments of the present disclosure, there is an advantage that a current crowding problem that may occur when a depth of a deep P-well becomes deeper than a trench may be alleviated, thereby making a current path uniform and reducing power loss and thermal stress.

In addition, according to at least one of the embodiments of the present disclosure, there is an advantage that trench bottom oxide protection and current spreading effects may be simultaneously satisfied by combining first and second bottom protection structures.

An additional scope of applicability of the present disclosure will become apparent from the detailed description below. However, since various changes and modifications within the spirit and scope of the present disclosure will be clearly understood by those skilled in the art, the detailed description and specific embodiments, such as preferred embodiments of the present disclosure, should be understood as being given merely by way of example.

### BRIEF DESCRIPTION OF THE DRAWINGS

Exemplary embodiments can be understood in more detail from the following description taken in conjunction with the accompanying drawings, in which:

FIGS. 1 to 21 sequentially illustrate processes for manufacturing a trench structure according to an embodiment of the present disclosure.

FIG. 22 is a view illustrating a structure of a SiC trench MOSFET having a trench bottom protection structure according to an embodiment of the present disclosure.

FIG. 23 is a view illustrating doping profiles of a general ion implantation (random implant) and a channeling implantation ([0001] axial channeling).

FIG. 24 is a conceptual diagram illustrating effects of a protection structure according to an embodiment of the present disclosure.

FIG. 25 is a view illustrating a reason why a protection structure according to an embodiment of the present disclosure is more effective in a deep P-well structure.

FIG. 26 is a view illustrating how a current path changes due to a protection structure according to an embodiment of the present disclosure.

FIG. 27 is a view illustrating A and B reference lines crossing a first bottom protection structure 1410, a second bottom protection structure 1111, and an epitaxial layer 200 for explaining a doping profile. FIG. 28 is a view illustrating doping profiles varying along the A and B reference lines.

### DETAILED DESCRIPTION

Hereinafter, embodiments disclosed in the present specification will be described in detail with reference to the accompanying drawings. The same or similar components are denoted by the same reference numerals regardless of reference numerals, and redundant descriptions thereof will be omitted. Suffixes “module” and “unit” used for components in the following description are given or used interchangeably merely for ease of writing the specification, and do not have distinct meanings or roles by themselves. In addition, in describing the embodiments disclosed in the present specification, when it is determined that a detailed description of related known technologies may obscure the gist of the embodiments disclosed herein, the detailed description thereof will be omitted. In addition, the accompanying drawings are merely for easily understanding the embodiments disclosed in the present specification, and the technical idea disclosed herein is not limited by the accompanying drawings, and should be understood to include all changes, equivalents, and substitutes included in the spirit and technical scope of the present disclosure.

Terms including an ordinal number, such as first, second, etc., may be used to describe various components, but the components are not limited by the terms. The terms are used only for the purpose of distinguishing one component from another component.

When a component is referred to as being “connected” or “coupled” to another component, it should be understood that the component may be directly connected or coupled to the other component, but other components may also exist therebetween. On the other hand, when a component is referred to as being “directly connected” or “directly coupled” to another component, it should be understood that no other component exists therebetween.

The singular expression may include the plural expression unless the context clearly dictates otherwise.

In the present application, it should be understood that terms such as “comprises” or “have” are intended to designate that features, numbers, steps, operations, components, parts, or combinations thereof described in the specification exist, and do not preclude the possibility of the existence or addition of one or more other features, numbers, steps, operations, components, parts, or combinations thereof.

A first bottom protection structure according to an embodiment of the present disclosure refers to a structure for forming a second conductivity type region at a bottom of a trench structure in a semiconductor layer of a first conductivity type, thereby reducing an electric field applied to a trench bottom oxide and preventing damage to the oxide.

This structure contributes to reducing a risk of oxide destruction due to a high electric field and improving reliability of a device.

The first bottom protection structure is designed to improve electrical characteristics at a bottom of the trench while optimizing current flow and channel resistance characteristics.

A second bottom protection structure according to an embodiment of the present disclosure refers to a layer designed to alleviate current crowding in which current concentrates in a specific region around a trench. The second bottom protection structure forms a first conductivity type region in a shape surrounding the first bottom protection structure in the semiconductor layer of the first conductivity type.

This structure reduces power loss and thermal stress by widely distributing current, while simultaneously reinforcing a protection effect on the trench bottom oxide.

The second bottom protection structure, in combination with the first bottom protection structure, serves to ensure uniformity of current flow and improve electrical performance and stability of a device.

When ions are implanted using a general random implant, it is difficult to implant to a depth of 1.5 μm or more in SiC unless a high energy of 1 MeV or more is used with special equipment.

In ion implantation, a channeling phenomenon refers to a phenomenon in which, when ion implantation is performed in a specific direction, ions penetrate deeper than an intended depth through empty spaces between aligned silicon atoms. In general, since a problem of implanting deeper than a desired depth occurs due to the channeling phenomenon, the channeling phenomenon acts as a negative factor in ion implantation, and there is a need to minimize its occurrence.

Hereinafter, in the present disclosure, a method of forming a source well structure having a deep well structure using such a channeling phenomenon will be described.

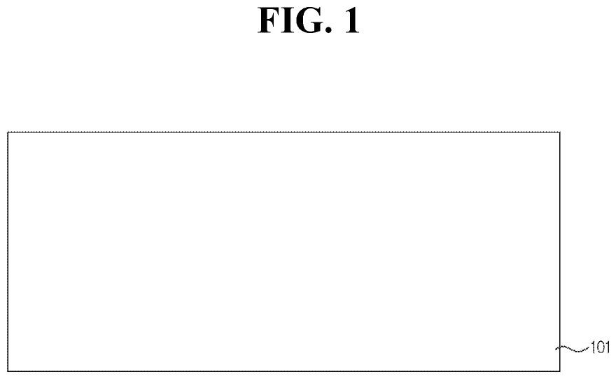

FIGS. 1 to 17 sequentially illustrate processes for manufacturing a trench structure according to an embodiment of the present disclosure.

Referring to FIG. 1, an n⁺-type SiC semiconductor substrate 101 serving as a base substrate is prepared. Hereinafter, although the semiconductor layer, and the first and second protection structures are described as being doped with n-type or p-type as an example, the present disclosure is not necessarily limited thereto and may be doped with an opposite type.

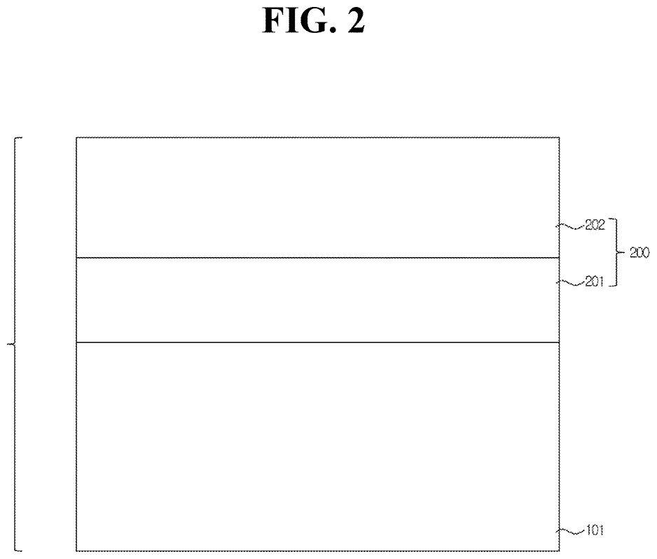

Next, referring to FIG. 2, an epitaxial layer 200 is formed on an upper surface of the SiC semiconductor substrate 101. The epitaxial layer 200 is formed by growing SiC on the upper surface of the SiC semiconductor substrate 101 through an epitaxial growth method.

In this step, the epitaxial layer 200 having a high-concentration region 201 and a low-concentration region 202 is formed by controlling an introduction amount of n-type impurities. Through this, a SiC semiconductor layer 210 including the SiC semiconductor substrate 101 and the epitaxial layer 200 is formed.

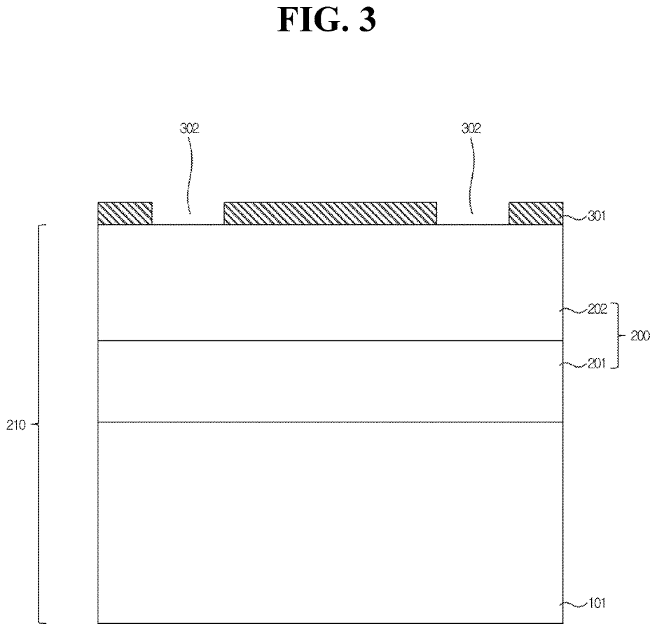

Subsequently, referring to FIG. 3, a mask 301 having a predetermined pattern is formed on the SiC semiconductor layer 210. The mask 301 has an opening 302 for selectively exposing. The opening 302 exposes a region on the SiC semiconductor layer 210 where a source well structure is to be formed.

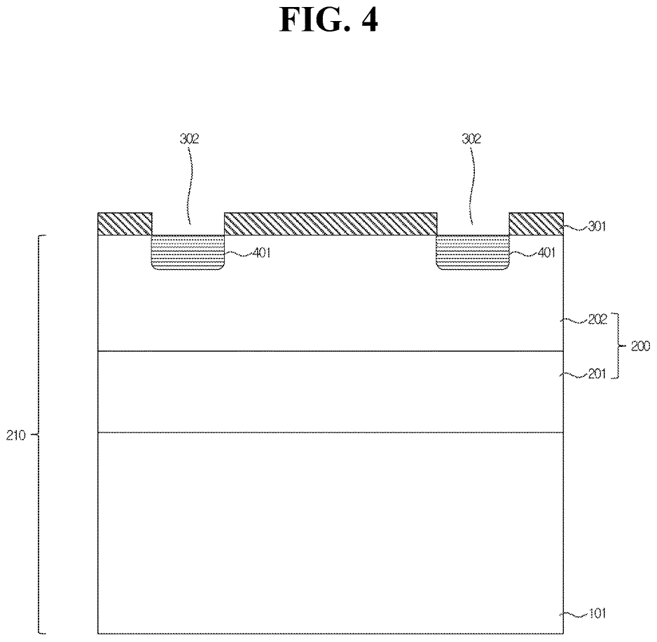

Subsequently, referring to FIG. 4, a source well structure 401 is formed in the SiC semiconductor layer 210. The source well structure 401 may be formed by introducing p-type impurities into the upper surface of the SiC semiconductor layer 210. The p-type impurities are introduced into the upper surface of the SiC semiconductor layer 210 through the mask 301.

The source well structure 401 according to an embodiment of the present disclosure is proposed to be formed by ion implantation utilizing a channeling phenomenon.

As described above, the channeling phenomenon refers to a phenomenon in which, when ion implantation is performed in a specific direction, ions penetrate deeper than an intended depth through empty spaces between aligned silicon atoms. In general, the channeling phenomenon is a phenomenon that should be avoided in semiconductor processes.

However, in the present disclosure, it is proposed to utilize such a channeling phenomenon to form the source well structure 401 with a sufficient depth.

More specifically, in the present disclosure, it is proposed to implant ions with the SiC semiconductor substrate 101 tilted at 4° (hereinafter referred to as channeling implantation). That is, the ion implantation according to an embodiment of the present disclosure is proposed to be performed in a state tilted at 3 to 5°.

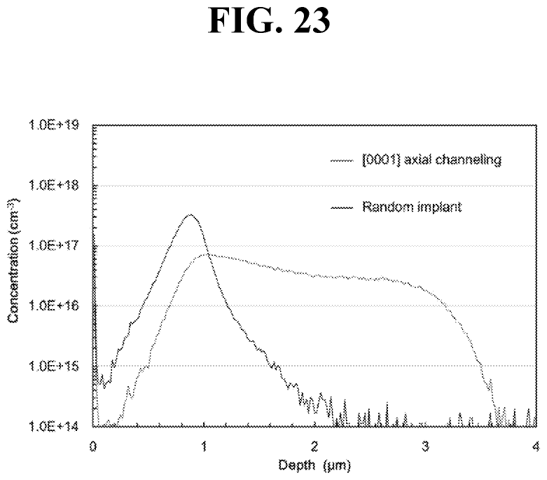

FIG. 23 is a view illustrating doping profiles of a general ion implantation (random implant) and a channeling implantation ([0001] axial channeling).

In the case of the general ion implantation, it may be confirmed that a peak is reached near approximately 1 μm and then decreases sharply. That is, it may be understood that deep implantation is difficult in the general ion implantation.

However, in the case of the channeling implantation, it may be confirmed that sufficient implantation occurs up to approximately 3 μm. That is, it may be confirmed that the channeling implantation may implant deeper than the general ion implantation under the same conditions.

Furthermore, in an embodiment of the present disclosure, it is proposed that the channeling implantation is performed at room temperature. While the general ion implantation is performed at a temperature higher than room temperature, the channeling implantation is proposed to be performed at room temperature between 20° C. and 50° C. This is because as the temperature increases, vibration of atoms becomes more active, and thus an implantation depth may become shallower. Since the process is performed at room temperature, a photo resist mask may be used instead of a general oxide mask, thereby enabling simplification of the process.

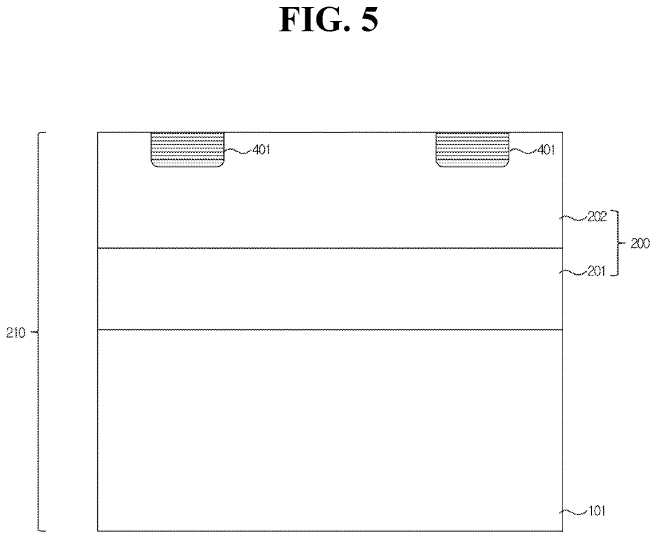

Referring to FIG. 5, the mask 301 is removed.

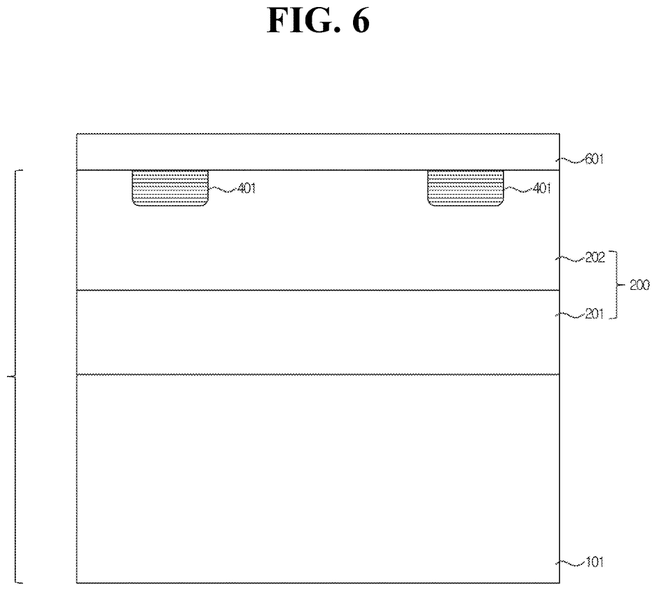

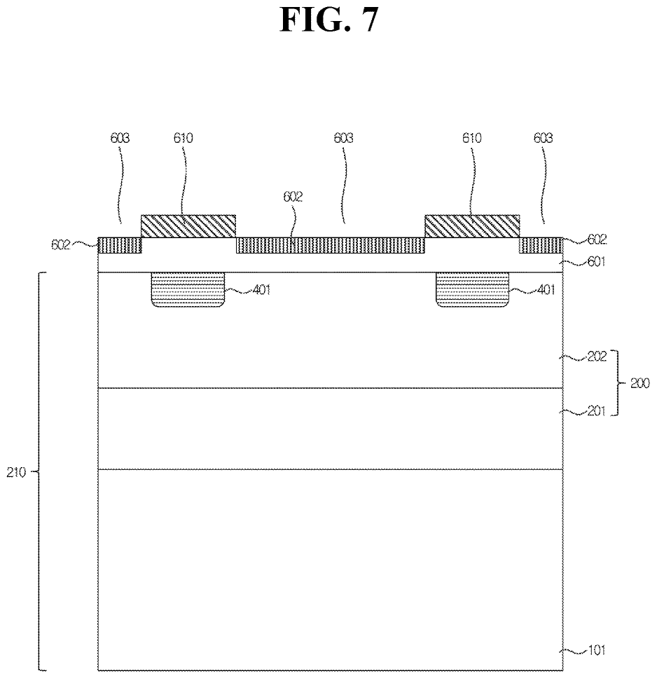

Referring to FIG. 6, a p-type body region 601 is formed on the upper surface of the SiC semiconductor layer 210. The body region 601 may be formed by introducing p-type impurities (random implant) into the upper surface of the SiC semiconductor layer 210.

Referring to FIG. 7, a mask 610 has an opening 603 for selectively exposing. The opening 603 exposes a region on the SiC semiconductor layer 210 where an n-type source region 602 is to be formed. Then, the n-type source region 602 is formed in a surface layer portion of the body region 601. The source region 602 may be formed by introducing n-type impurities into the surface layer portion of the body region 601. Formation of the source region 602 is performed at a high temperature using an oxide mask.

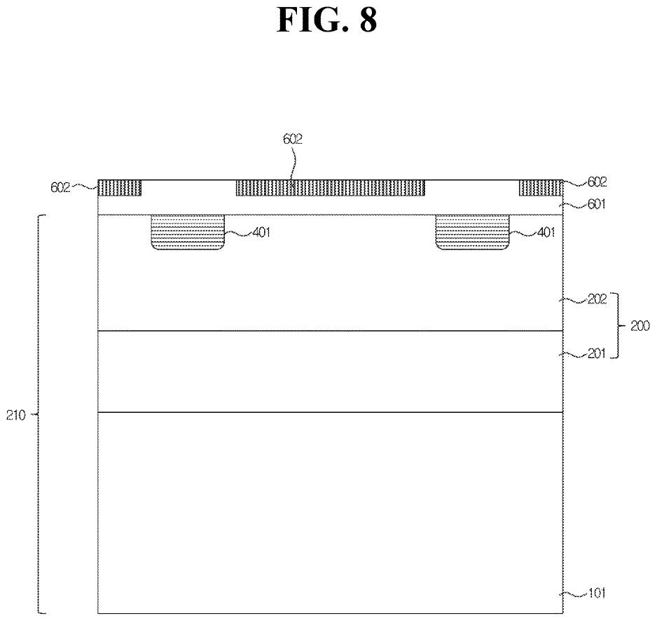

Referring to FIG. 8, the mask 610 is removed.

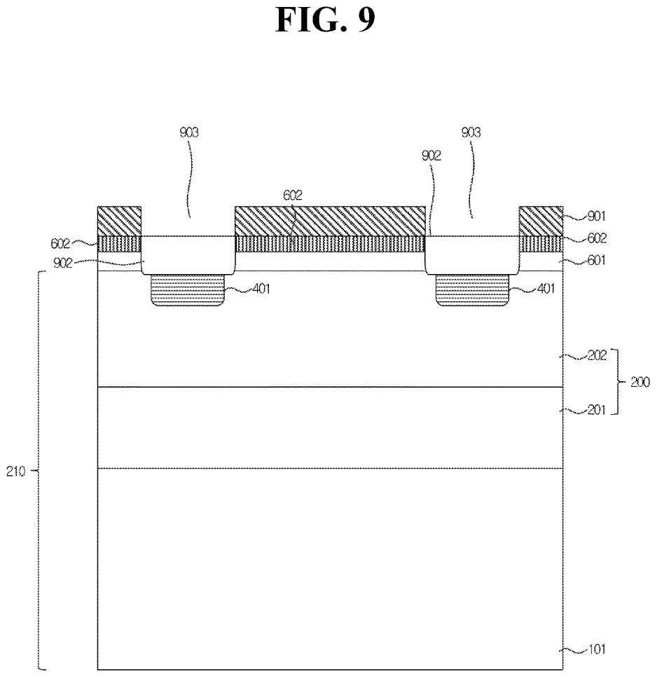

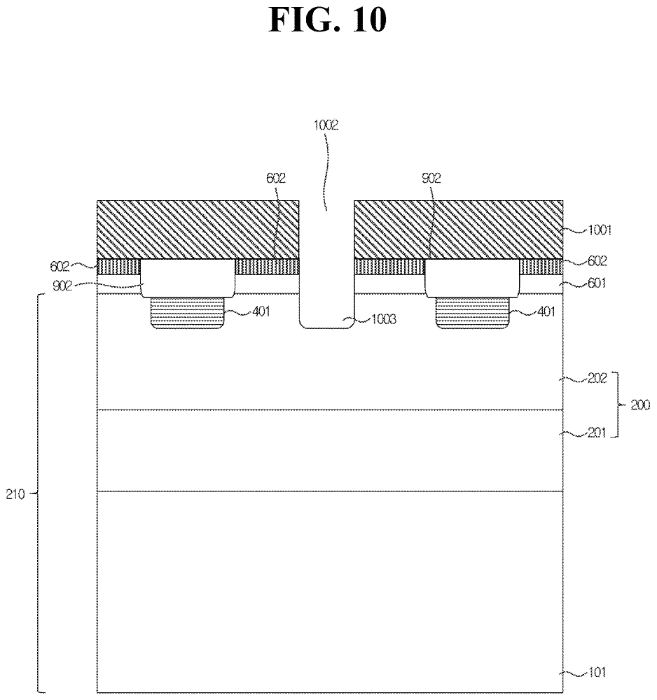

Referring to FIG. 9, a mask 901 having a predetermined pattern is formed on the upper surface of the SiC semiconductor layer 210. The mask 901 has a plurality of openings 903 for selectively exposing a region where a contact region 902 is to be formed.

Next, the contact region 902 is formed in a surface layer portion of the upper surface of the SiC semiconductor layer 210. The contact region 902 is formed by introducing p-type impurities into the upper surface of the SiC semiconductor layer 210. The p-type impurities are introduced into the upper surface of the SiC semiconductor layer 210 through the mask 901, and then the mask 901 is removed. Formation of the contact region 902 is performed at a high temperature using an oxide mask.

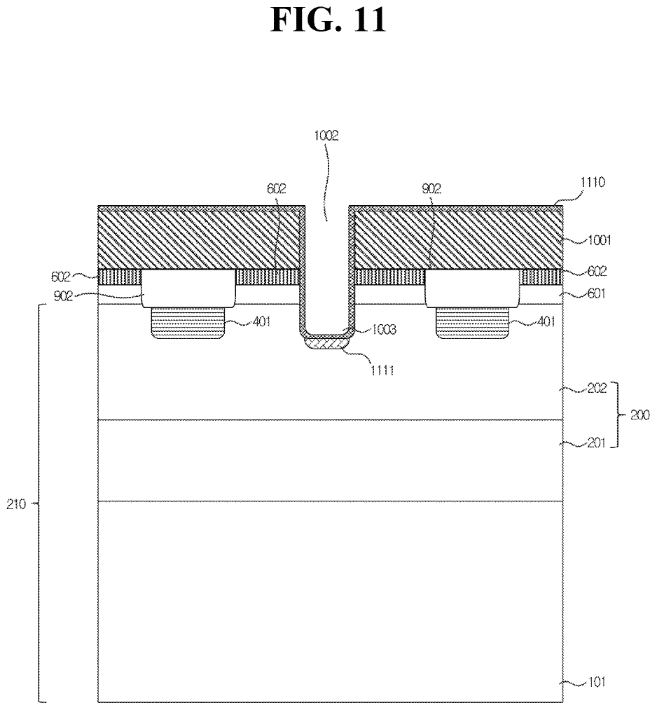

Referring to FIG. 10, a mask 1001 having a predetermined pattern is formed thereon. The mask 1001 has an opening 1002 for selectively exposing a region where a gate trench 1003 is to be formed.

Next, unnecessary portions of the SiC semiconductor layer 210 are removed by an etching method (e.g., a dry etching method) through the mask 1001. In this step, the gate trench 1003 is formed by removing unnecessary portions of the epitaxial layer 200.

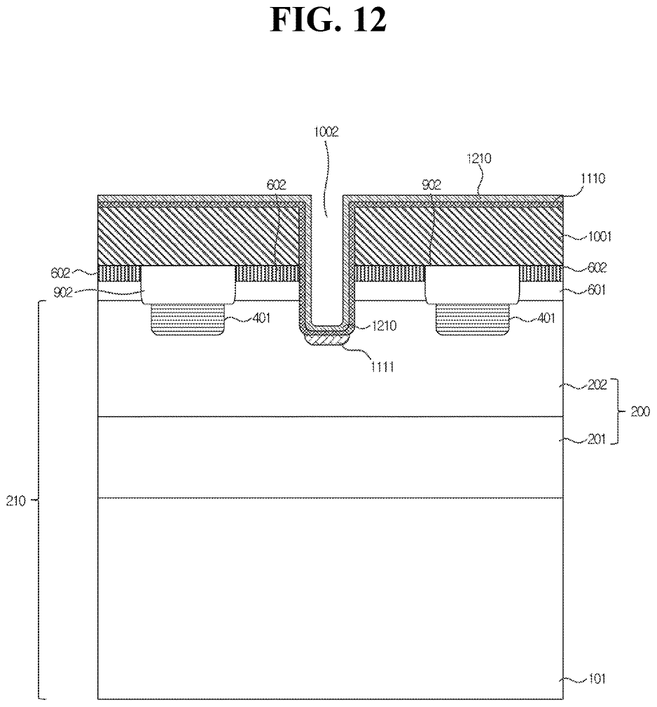

Referring to FIG. 11, a thin oxide layer 1110 is formed before forming the first bottom protection structure.

The thin oxide layer 1110 is a thin but uniform layer and plays an important role in ensuring electrical and physical stability of the gate trench 1003 structure during the process. The thin oxide layer 1110 protects an inner surface in the gate trench 1003 structure so that damage does not occur in subsequent processes (e.g., doping, deposition, etching, etc.).

In addition, the thin oxide layer 1110 improves interface characteristics between the first bottom protection structure or other structures to optimize electrical performance, and serves to reduce defects (dangling bonds) at the interface and minimize electrical loss.

Subsequently, a first N-type implant is performed to form a second bottom protection structure 1111 at the bottom of the gate trench 1003. This is to suppress potential current crowding associated with the first bottom protection structure. A doping concentration and depth are designed to optimize trench bottom oxide protection and electrical characteristics.

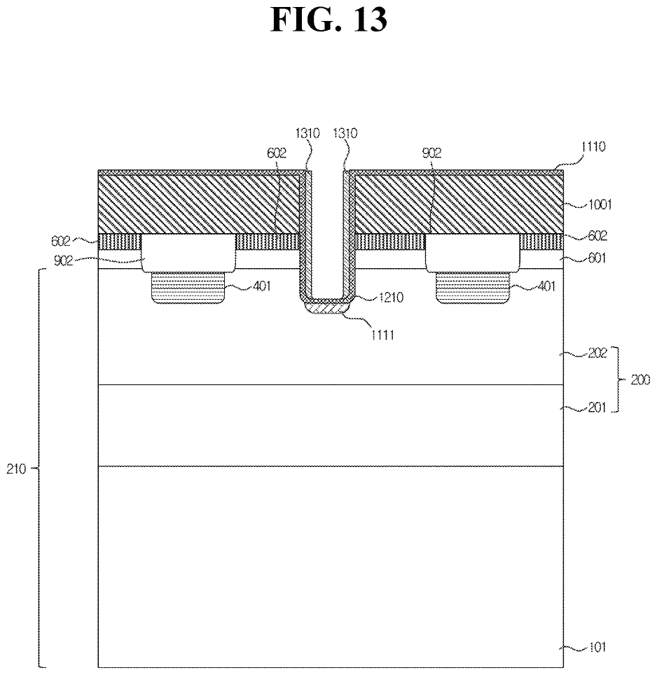

Subsequently, referring to FIG. 12, the interior of the gate trench 1003 is filled with Poly-Si 1210. Then, referring to FIG. 13, the Poly-Si 1210 is etched to form a spacer 1310.

The spacer 1310 serves to expose only a desired region and protect the remainder, thereby forming a required structure in subsequent processes such as etching or ion implantation. The Poly-Si 1210 is deposited to fill the gate trench 1003 structure, and then the spacer 1310 is formed.

The oxide layer 1110 according to an embodiment of the present disclosure is proposed to form (maintain) an R-Tox (Remaining Oxide Thickness) to protect a shape at the bottom of the gate trench 1003 when the Poly-Si 1210 is subsequently removed. The remaining oxide serves to ensure stability at the bottom of the gate trench 1003 during the Poly-Si 1210 removal process.

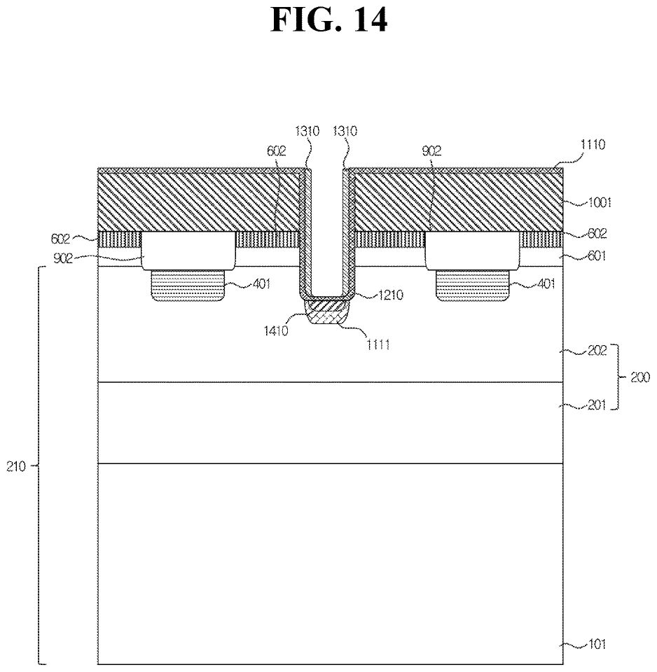

Subsequently, referring to FIG. 14, a P-type implant is performed to form a first bottom protection structure 1410 at the bottom of the gate trench 1003. Then, a second N-type implant is performed to reinforce the previously formed second bottom protection structure 1111. Through this, current spreading is facilitated so that current flows more uniformly at the bottom of and around the gate trench 1003.

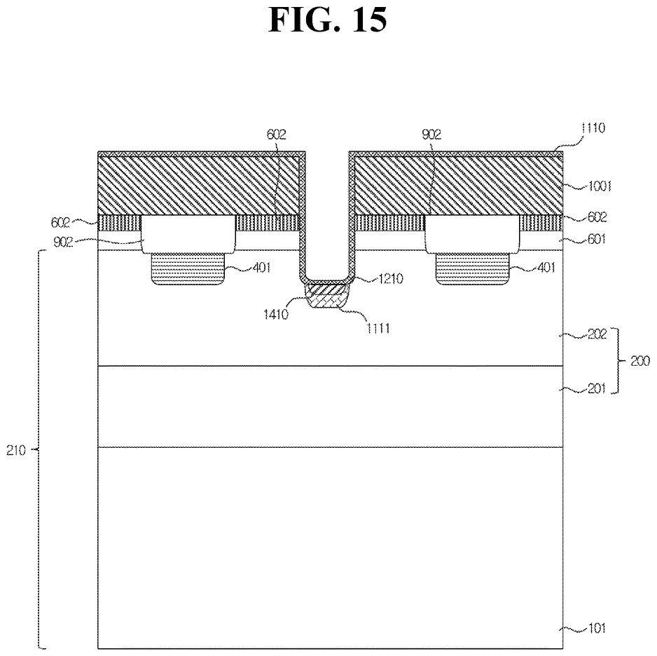

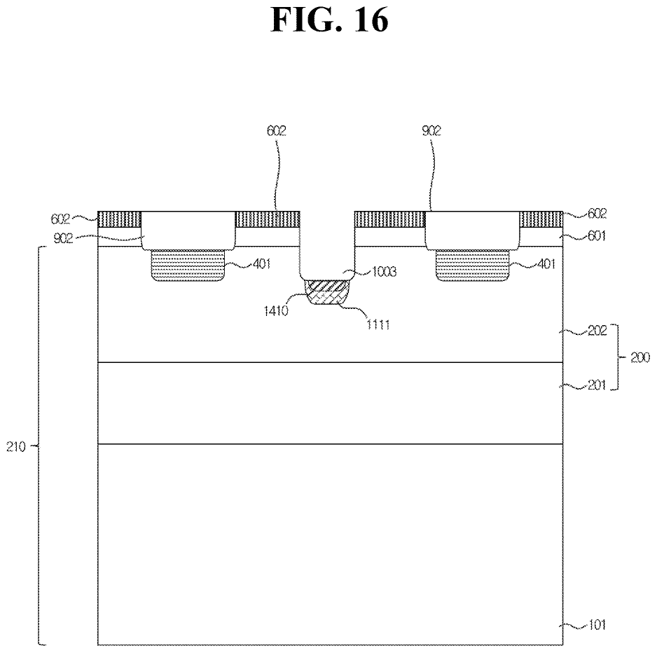

Referring to FIG. 15, the spacer 1310 is removed. Subsequently, referring to FIG. 16, the oxide layer 1210 and the mask 1001 are removed.

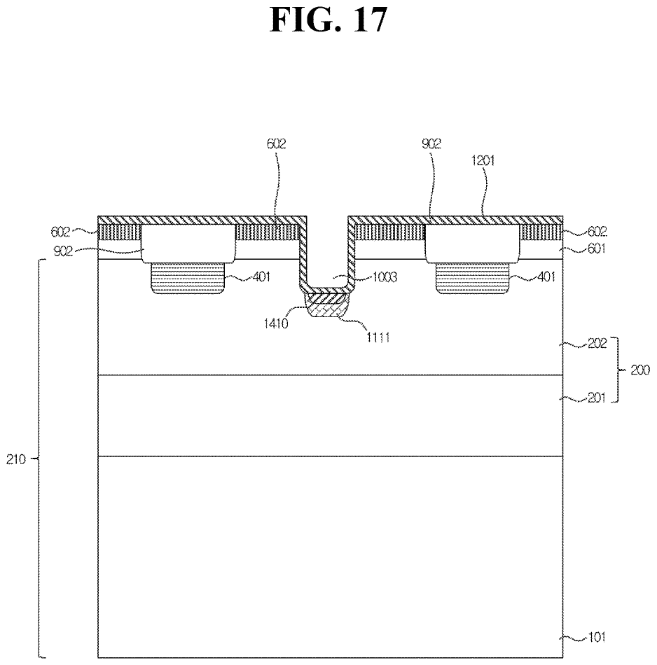

Referring to FIG. 17, a gate insulating layer 1201 is formed on the upper surface of the SiC semiconductor layer 210. The gate insulating layer 1201 may include silicon oxide. The gate insulating layer 1201 may be formed by a CVD method or a thermal oxidation method.

The gate insulating layer 1201 having such a configuration is formed by adjusting conditions of the CVD method or the thermal oxidation method. For example, in the CVD method or the thermal oxidation method, predetermined conditions such as gas flow rate, gas type, gas ratio, gas supply time, ambient temperature, and the like must be adjusted.

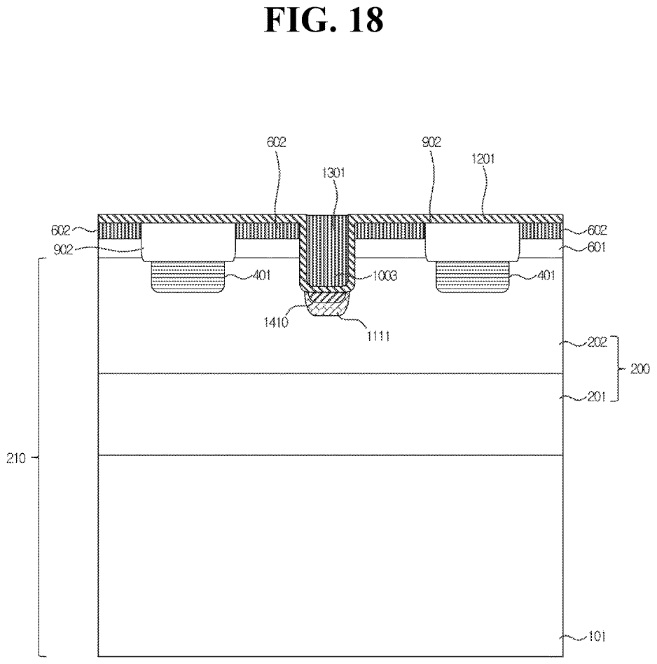

Referring to FIG. 18, a gate electrode 1301 fills the gate trench 1003. The gate electrode 1301 may include polysilicon. The gate electrode 1301 may be formed by a CVD method. The CVD method may be a LP-CVD (low-pressure CVD) method.

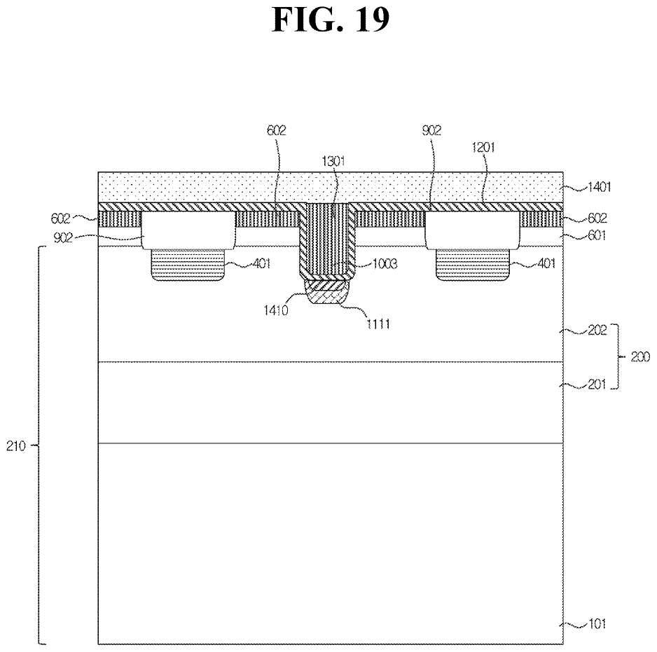

Referring to FIG. 19, an insulating layer 1401 is formed on the upper surface of the SiC semiconductor layer 210. The insulating layer 1401 may include silicon oxide or silicon nitride. The insulating layer 1401 may be formed by a CVD method.

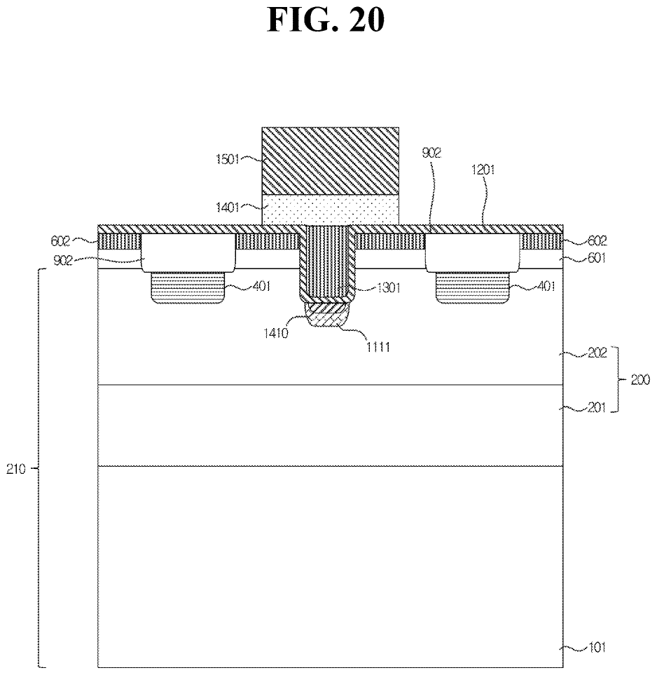

Referring to FIG. 20, a mask 1501 having a predetermined pattern is formed on the insulating layer 1401. Next, unnecessary portions of the insulating layer 1401 and the gate insulating layer 1201 are removed. The unnecessary portions of the insulating layer 1401 and the gate insulating layer 1201 may be removed by an etching method (e.g., a dry etching method) through the mask 1501.

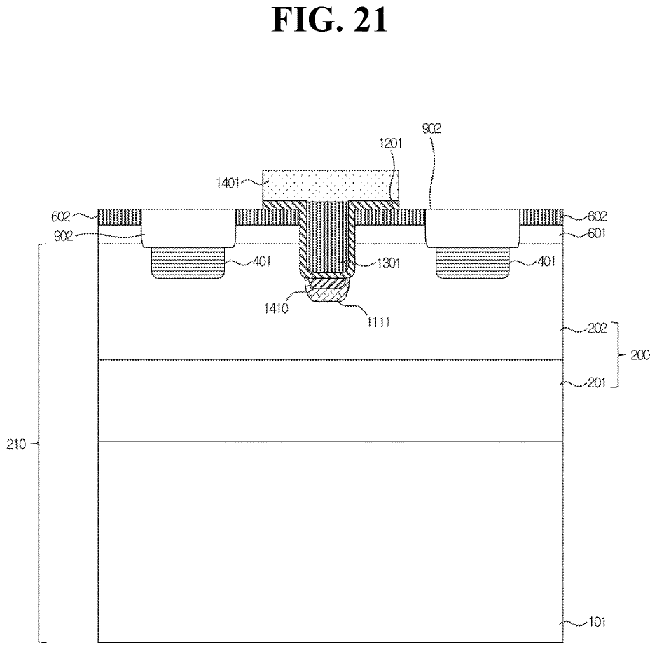

Subsequently, referring to FIG. 21, the mask 1501 is removed.

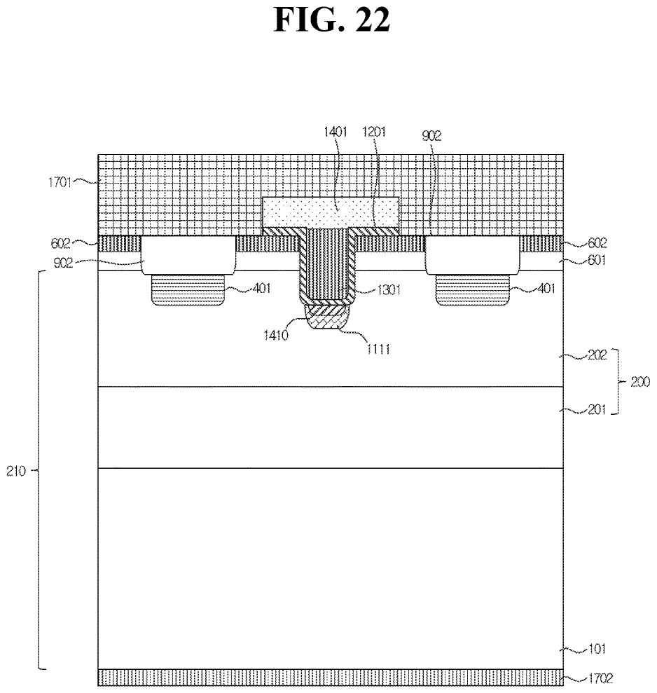

FIG. 22 is a view illustrating a structure of a SiC trench MOSFET having a trench bottom protection structure according to an embodiment of the present disclosure.

Referring to FIG. 22, a source electrode 1701 is formed on the insulating layer 1401. A drain electrode 1702 is formed on a lower surface of the SiC semiconductor layer 210.

Referring to FIG. 22, a structure of a SiC trench MOSFET according to an embodiment of the present disclosure will be described.

The SiC semiconductor layer 210 has a stacked structure including a SiC semiconductor substrate 101 including SiC single crystal and an n-type epitaxial layer 200 including SiC single crystal.

The drain electrode 1702 is formed on the lower surface of the SiC semiconductor layer 210. The SiC semiconductor substrate 101 is formed as an n⁺ type drain region. The SiC epitaxial layer 200 is formed as an n-type drain drift region.

An n-type impurity concentration of the SiC semiconductor substrate 101 may range from a minimum of 1.0×10¹⁸ cm⁻³ to a maximum of 1.0×10²¹ cm⁻³. An n-type impurity concentration of the SiC epitaxial layer 200 may range from a minimum of 1.0×10¹⁵ cm⁻³ to a maximum of 1.0×10¹⁷ cm⁻³. Here, the “impurity concentration” in the present description refers to a peak value of the impurity concentration.

A trench gate structure includes the gate trench 1003, the gate insulating layer 1201, the gate electrode 1301, the second bottom protection structure 1111, and the first bottom protection structure 1410.

The gate trench 1003 is formed by excavating downward from the upper surface of the SiC semiconductor layer 210.

The gate insulating layer 1201 is formed in a film shape along sidewalls and a bottom surface of the gate trench 1003. The gate insulating layer 1201 forms a concave space inside the gate trench 1003.

The gate insulating layer 1201 may include silicon oxide. The gate insulating layer 1201 may include one or more of undoped silicon, silicon nitride, aluminum oxide, aluminum nitride, or aluminum oxynitride in addition to silicon oxide.

The gate electrode 1301 is inserted into the concave space formed by the gate insulating layer 1201. The gate electrode 1301 may include conductive polysilicon. The gate electrode layer may include one or more of titanium, nickel, copper, aluminum, silver, gold, titanium nitride, or tungsten in addition to conductive polysilicon.

The second bottom protection structure 1111 refers to a layer designed to alleviate current crowding in which current concentrates in a specific region around the trench.

The first bottom protection structure 1410 is a structure for forming a P-type region at a bottom of the trench structure, thereby reducing an electric field applied to the trench bottom oxide and preventing damage to the oxide.

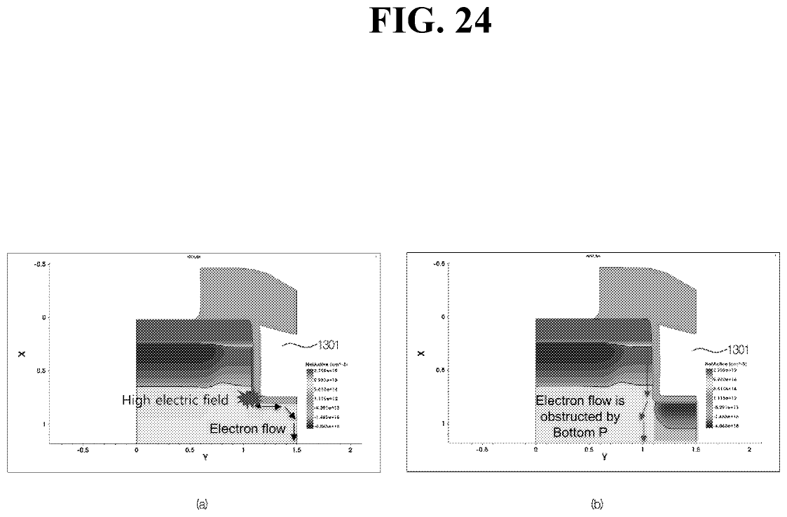

Hereinafter, a protection effect by the second bottom protection structure 1111 and the first bottom protection structure 1410 will be described with reference to FIG. 24.

FIG. 24 is a conceptual diagram illustrating effects of a protection structure according to an embodiment of the present disclosure.

FIG. 24(a) illustrates an electron path when there is no protection structure, and FIG. 24(b) illustrates an electron path changed by the protection structure.

The protection structures, i.e., the second bottom protection structure 1111 and the first bottom protection structure 1410, integrally reinforce the trench bottom oxide protection and current spreading functions, thereby improving stability and power efficiency of a device.

FIG. 24(a) shows that, when there is no protection structure, electrons flow down along sidewalls of the gate trench 1301 and then flow along a bottom surface of the gate trench 1301 at a bottom corner of the gate trench 1301. However, as shown in FIG. 24(b), when the protection structure is formed, it may be confirmed that an increase in resistance may be accompanied by the flow of electrons being obstructed.

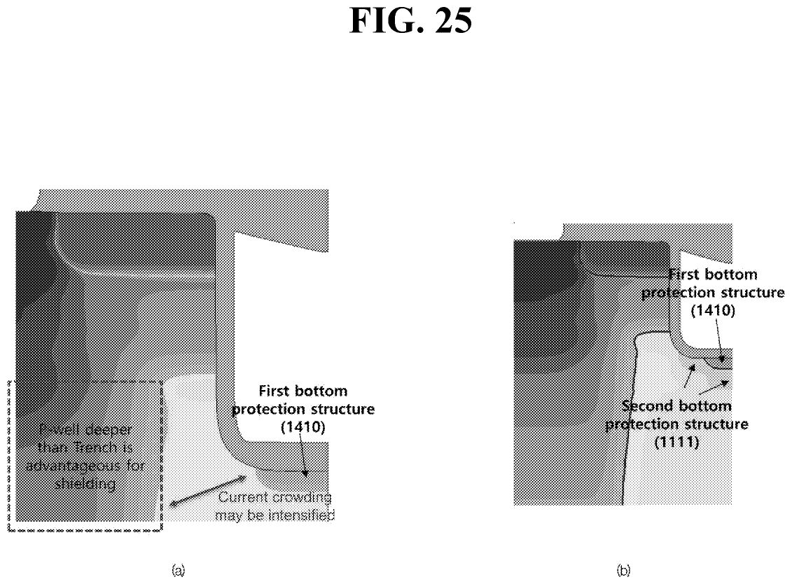

In particular, the source well structure 401 according to an embodiment of the present disclosure is proposed to be formed as a deep P-well structure. An enhanced effect of the protection structure in the case of such a source well structure 401 will be described with reference to FIG. 25.

FIG. 25 is a view illustrating a reason why a protection structure according to an embodiment of the present disclosure is more effective in a deep P-well structure.

Referring to FIG. 25(a), a narrowing channel due to the deep P-well structure is illustrated.

As illustrated, when the source well structure 401 is formed as a deep P-well structure and a depth of the deep P-well structure becomes deeper than the gate trench 1301, a narrowing region of the channel is formed (i.e., a current path becomes narrower), and current crowding may be intensified.

Referring to FIG. 25(b), when the second bottom protection structure 1111 is formed, current crowding may be alleviated and trench bottom oxide protection may be simultaneously satisfied.

Hereinafter, current flows when only the first bottom protection structure 1410 is formed and when both the first bottom protection structure 1410 and the second bottom protection structure 1111 are formed will be compared, and an effect of the second bottom protection structure 1111 will be described.

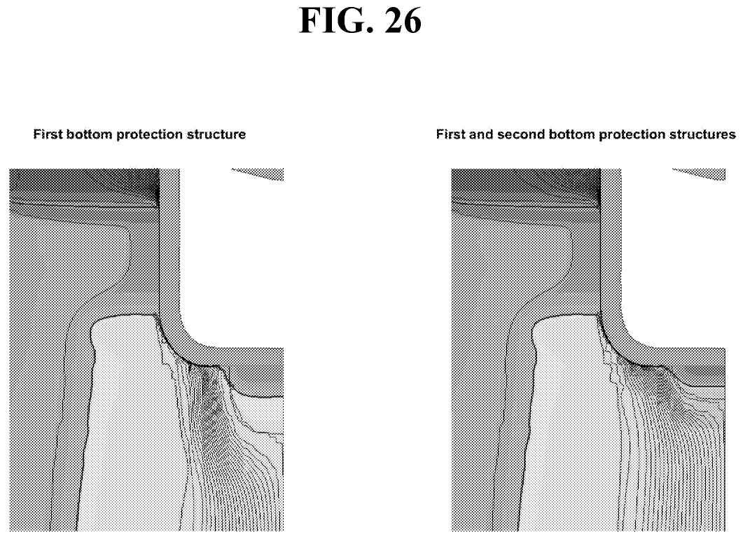

FIG. 26 is a view illustrating how a current path changes due to a protection structure according to an embodiment of the present disclosure.

FIG. 26(a) illustrates current flow when only the first bottom protection structure 1410 is formed, and FIG. 26(b) illustrates current flow when both the first bottom protection structure 1410 and the second bottom protection structure 1111 are formed.

In the drawings, denser current lines represent a state of more severe current crowding, and wider spacing between current lines represents a state of alleviated current crowding. It may be confirmed that the current spacing in FIG. 26(b) is less dense than in FIG. 26(a). Therefore, it may be understood that current crowding suppression is more effective when both the first bottom protection structure 1410 and the second bottom protection structure 1111 are formed together than when only the first bottom protection structure 1410 is formed.

Returning to FIG. 22, the structure will be described. A p-type impurity concentration of the source well structure 401 may range from a minimum of 1.0×10¹⁷ cm⁻³ to a maximum of 1.0×10¹⁹ cm⁻³.

The p-type body region 601 is formed on the upper surface of the SiC semiconductor layer 210. The body region 601 is formed in a region between the gate trench 1003 and the source well structure 401.

The body region 601 is exposed from a sidewall of the gate trench 1003 and a sidewall of the source well structure 401.

A p-type impurity concentration of the body region 601 may range from a minimum of 1.0×10¹⁶ cm⁻³ to a maximum of 1.0×10¹⁹ cm⁻³. The p-type impurity concentration of the body region 601 may be substantially the same as a p-type impurity concentration of the source well structure 401.

An n+ type source region 602 is formed in a surface layer portion of the body region 601. The source region 602 is formed in the surface layer portion of the body region 601 along a sidewall of the gate trench 1003.

A plurality of p+ type contact regions 902 are formed in the surface layer portion of the body region 601. The contact region 902 is formed in the surface layer portion of the body region 601 along a sidewall of the source well structure 401. A p-type impurity concentration of the contact region 902 may range from a minimum of 1.0×10¹⁸ cm⁻³ to a maximum of 1.0×10²¹ cm⁻³.

The insulating layer 1401 is formed on the upper surface of the SiC semiconductor layer 210. The insulating layer 1401 entirely covers the trench gate structure.

The source electrode 1701 is formed on the insulating layer 1401.

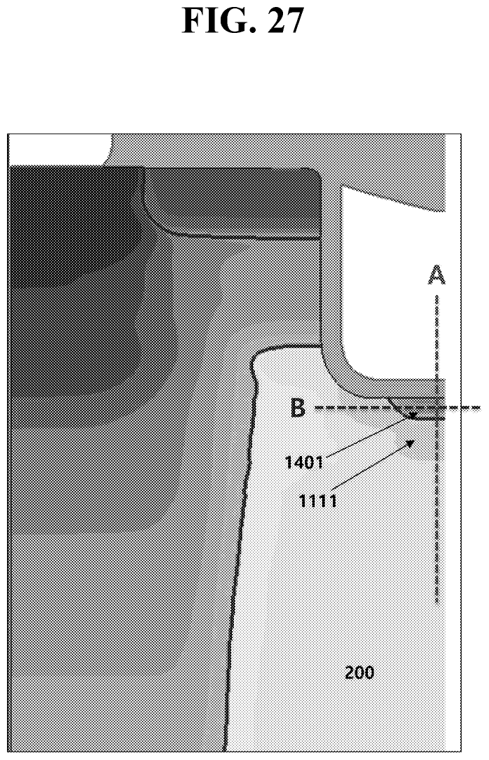

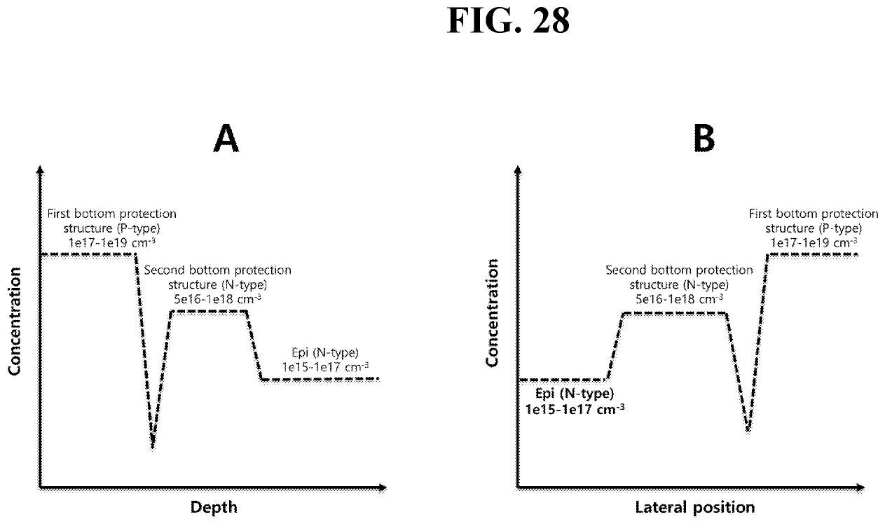

Doping profiles among the above-described first bottom protection structure 1410, the second bottom protection structure 1111, and the epitaxial layer 200 will be described with reference to FIGS. 27 and 28.

FIG. 27 is a view illustrating A and B reference lines crossing the first bottom protection structure 1410, the second bottom protection structure 1111, and the epitaxial layer 200 for explaining a doping profile. FIG. 28 is a view illustrating doping profiles varying along the A and B reference lines.

Looking at the A reference line first, the A reference line crosses the first bottom protection structure 1410, the second bottom protection structure 1111, and the epitaxial layer 200 in order in a depth direction (from top to bottom). The B reference line crosses the first bottom protection structure 1410, the second bottom protection structure 1111, and the epitaxial layer 200 in order in a horizontal direction (from left to right).

The first bottom protection structure 1410 according to an embodiment of the present disclosure is a P-type structure formed to a predetermined depth downward from the bottom of the trench.

The second bottom protection structure 1111 according to an embodiment of the present disclosure is an N-type structure provided in a shape surrounding the P-type structure.

The P-type structure and the N-type structure are provided to form a PN junction at the bottom of the trench to protect a bottom of the trench.

A doping concentration of the first bottom protection structure 1410 is P-type ranging from approximately 1.0×10¹⁷ cm⁻³ to a maximum of 1.0×10¹⁹ cm⁻³, a doping concentration of the second bottom protection structure 1111 is N-type ranging from approximately 5.0×10¹⁶ cm⁻³ to a maximum of 1.0×10¹⁸ cm⁻³, and a doping concentration of the epitaxial layer 200 is N-type ranging from approximately 1.0×10¹⁵ cm⁻³ to a maximum of 1.0×10¹⁷ cm⁻³.

That is, the second bottom protection structure 1111 is provided in a hemispherical shape at the bottom of the trench, and the first bottom protection structure 1410 is inserted inside the hemispherical shape, such that the first bottom protection structure 1410 is provided in a shape surrounded by the second bottom protection structure 1111.

In addition, the first bottom protection structure 1410 and the second bottom protection structure 1111 form a PN junction at the bottom of the trench.

Although embodiments of the SiC trench MOSFET forming a deep well structure and the method for manufacturing the same according to the present disclosure have been described above, these are described as at least one embodiment, and the technical idea, configuration, and operation of the present disclosure are not limited thereby.

The scope of the technical idea of the present disclosure is not limited by the drawings or the description referring to the drawings. In addition, the concept and embodiments of the present disclosure presented herein may be used as a basis for modifying or designing other structures for performing the same purpose of the present disclosure by those skilled in the art. Such modified or altered equivalent structures by those skilled in the art are bound by the technical scope of the present disclosure described in the claims, and various changes, substitutions, and modifications are possible without departing from the spirit or scope of the present disclosure described in the claims.

What is claimed is:

1. A SiC MOSFET comprising: a semiconductor layer of a first conductivity type;
a gate trench formed on an upper surface of the semiconductor layer; a source well structure of a second conductivity type formed on the upper surface of the semiconductor layer at a predetermined distance from the gate trench;
a body region of the second conductivity type formed on the upper surface between the gate trench and the source well structure;
a source region of the first conductivity type formed on an upper surface of the body region; and
a trench bottom protection structure provided at a bottom of the gate trench, wherein the trench bottom protection structure comprises: a first bottom protection structure forming a second conductivity type region formed to a predetermined depth downward from a bottom of the trench; and
a second bottom protection structure having a shape surrounding the first bottom protection structure and forming a first conductivity type region, wherein the second bottom protection structure is provided in a hemispherical shape at the bottom of the trench, and the first bottom protection structure is inserted inside the hemispherical shape, such that a bottom and sides of the first bottom protection structure are surrounded by the second bottom protection structure, and wherein the second bottom protection structure is formed being confined to a region directly below the bottom of the trench, contacts at least a portion of the region below the bottom of the trench, and does not extend upward along an outer sidewall of the trench.

2. The SiC MOSFET of claim 1, wherein a doping concentration of the second bottom protection structure is formed higher than a doping concentration of the semiconductor layer.

3. The SiC MOSFET of claim 2, wherein the first bottom protection structure is a structure forming a second conductivity type region at the bottom of the trench in order to reduce an electric field applied to a trench bottom oxide.

4. The SiC MOSFET of claim 2, wherein the second bottom protection structure is a structure forming a first conductivity type region surrounding the first bottom protection structure in order to widely distribute current and reduce power loss and thermal stress.

5. The SiC MOSFET of claim 1, wherein a depth of the source well structure is formed deeper than a bottom of the gate trench.

6. A method for manufacturing a SiC MOSFET, the method comprising:
forming a body region of a second conductivity type on an upper surface of a semiconductor layer of a first conductivity type;
forming a source region of the first conductivity type on an upper surface of the body region;
forming a gate trench on the upper surface of the semiconductor layer;
forming a source well structure of the second conductivity type on the upper surface of the semiconductor layer at a predetermined distance from the gate trench; and
forming a trench bottom protection structure at a bottom of the formed gate trench, wherein the forming of the trench bottom protection structure comprises:
performing a first conductivity type implant on a bottom of the trench to form a second bottom protection structure;
filling an interior of the trench with Poly-Si; etching the filled Poly-Si to form a spacer;
performing a second conductivity type implant on the bottom of the trench to form a first bottom protection structure;
additionally performing the first conductivity type implant to reinforce the second bottom protection structure; and
removing the formed spacer.

7. The method of claim 6, wherein the trench bottom protection structure comprises: a first bottom protection structure forming a second conductivity type region formed to a predetermined depth downward from the bottom of the trench; and a second bottom protection structure having a shape surrounding the first bottom protection structure and forming a first conductivity type region, wherein a doping concentration of the second bottom protection structure is formed higher than a doping concentration of the semiconductor layer.

8. The method of claim 7, wherein the first bottom protection structure is a structure forming a second conductivity type region at the bottom of the trench in order to reduce an electric field applied to a trench bottom oxide.

9. The method of claim 7, wherein the second bottom protection structure is a structure forming a first conductivity type region surrounding the first bottom protection structure in order to widely distribute current and reduce power loss and thermal stress.

10. The method of claim 6, wherein a depth of the source well structure is formed deeper than a bottom of the gate trench.
